(19) United States
(12) Patent Application Publication
(10) Pub. No.: US 2026/0045450 A1
(43) Pub. Date: Feb. 12, 2026

(54) SYSTEM AND METHOD TO SPECIFY A FREQUENCY MATCHING MARGIN FOR SUBSTRATE PROCESSING APPARATUS

(71) Applicant: ASM IP Holding B.V., Almere (NL)

(72) Inventor: Songwhe Herr, Seongna-si (KR)

(21) Appl. No.: 19/291,903

(22) Filed: Aug. 6, 2025

Related U.S. Application Data
(60) Provisional application No. 63/681,294, filed on Aug. 9, 2024.

(51) Int. Cl. H01J 37/32

(52) U.S. Cl. CPC H01J 37/32183

(57) ABSTRACT

A substrate processing apparatus with plasma control capabilities is disclosed. The apparatus comprises, a radio frequency (RF) source, a plasma chamber, and a plasma control system comprising: an impedance matching network comprising a first variable impedance matching device and a second variable impedance matching device; and a control circuit configured to: determine a first parameter of the first variable impedance matching device and a second parameter of the second variable impedance matching device, and a reflected RF power value (Pᵣ) reflected back to the RF source, determine a matching point (MP) where the Pᵣ is a specific value (P₀), determine a plurality of matching edge points representing an edge RF power value (P_{E}) that is greater than P₀ by a predetermined margin (P_{M}) based on the MP, wherein P_{E}=P₀+P_{M}, and determine at least one of a size and a center location of an impedance matching area.

### CROSS-REFERENCE TO RELATED APPLICATIONS

This application claims priority to U.S. Provisional Patent Application Ser. No. 63/681,294 filed Aug. 9, 2024 titled SYSTEM AND METHOD TO SPECIFY A RADIO FREQUENCY MATCHING MARGIN FOR SUBSTRATE PROCESSING APPARATUS, the disclosure of which is hereby incorporated by reference in its entirety.

### FIELD OF INVENTION

The present disclosure relates generally to a plasma control system and its method in a substrate processing apparatus, more specifically to plasma control in a substrate processing apparatus.

### BACKGROUND OF THE DISCLOSURE

In making semiconductor devices such as microprocessors, memory chips, and another integrated circuits, the semiconductor device fabrication process uses plasma processing at different stages of fabrication. Plasma processing involves energizing a gas mixture by imparting energy to the gas molecules by the introduction of RF (radio frequency) energy into the gas mixture. This gas mixture is typically contained in a vacuum chamber, also called a plasma chamber, and the RF energy is introduced through electrodes or other means in the chamber. In a typical plasma process, the RF generator generates power at the desired RF frequency and power, and this power is transmitted through the RF cables and networks to the plasma chamber.

To provide efficient transfer of power from the RF generator to the plasma chamber, an RF matching network is positioned between the RF generator and the plasma chamber. The purpose of the RF matching network is to transform the plasma impedance to a value suitable for the RF generator. In many cases, particularly in the semiconductor fabrication processes, the RF power is transmitted through 50 Ohm coaxial cables and the system impedance (output impedance) of the RF generators is also 50 Ohm. On the other hand, the impedance of the plasma, driven by the RF power, varies based on the plasma chemistry and other conditions inside the plasma chamber. This impedance must be transformed to non-reactive 50 Ohm (i.e., 50+j0) for maximum power transmission. RF matching network performs this task of continuously transforming the plasma impedance to 50 Ohm for the RF generator. In most cases, this transformation is done such that the impedance on the input side of the RF matching network becomes 50+j0 Ohm, that is, a purely resistive 50 Ohm.

An RF matching network may comprise variable capacitors and a microprocessor-based control circuit to control the capacitors. The value and size of the variable capacitors are influenced by the power handling capability, frequency of operation, and impedance range of the plasma chamber. The predominant variable capacitor in use in RF matching networks is the vacuum variable capacitor (VVC). The VVC is an electromechanical device, consisting of two concentric metallic rings that move in relation to each other to change the capacitance. An alternative to the VVC is the electronically variable capacitor (EVC) (see, e.g., U.S. Pat. No. 7,251,121, incorporated herein by reference in its entirety), which is faster than the VVC and thus enables a reduction in semiconductor processing tune time. EVC-based matching networks are a type of solid state matching network.

The operating principle of the RF matching network is to transform the chamber impedance by changing the EVC values to minimize the RF reflected power at a matcher input. From the EVC values alone, it is difficult to tell how stable these EVC values are. The process stability is evaluated by the reflected power level and the EVC values of the matching condition. But there is an ambiguous property of how much allowance to make for judging stability.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, a substrate processing apparatus, comprising: a radio frequency (RF) source configured to generate an RF; a plasma chamber configured to process substrates; and a plasma control system, wherein the plasma control system comprising: an impedance matching network (IMN), operably coupled between the RF source and the plasma chamber, comprising a first variable impedance matching device (1^{st} VIMD) and a second variable impedance matching device (2^{nd} VIMD); and a control circuit operably coupled to the impedance matching network (IMN), the control circuit is configured to: determine a first parameter (C1) of the first variable impedance matching device (1^{st} VIMD), a second parameter (C2) of the second variable impedance matching device (2^{nd} VIMD), and a reflected radio frequency (RF) power value (Pᵣ) reflected back to the radio frequency (RF) source, wherein Pᵣ varies depending on the values of the first parameter (C1) and the second parameter (C2); determine a matching point (MP) where the Pᵣ is a specific value (P₀); determine, based on the matching point (MP), a plurality of matching edge points (MEPs) representing an edge radio frequency (RF) power value (P_{E}) that is greater than P₀ by a predetermined margin (P_{M}), wherein P_{E}=P₀+P_{M}; and determine at least one of a size and a center location of an impedance matching area (IMA) determined by the plurality of matching edge points (MEPs).

In accordance with another embodiment there may be provided, a method of determining an impedance matching area (IMA) in a plasma control system for a substrate processing apparatus, the method comprising: determining a first parameter (C1) of a first variable impedance matching device (1^{st} VIMD), a second parameter (C2) of a second variable impedance matching device (2^{nd} VIMD), and a reflected radio frequency (RF) power value (Pᵣ) reflected back to a radio frequency (RF) source, wherein Pᵣ varies depending on the values of the first parameter (C1) and the second parameter (C2); determining a matching point (MP) wherein Pᵣ is a specific value (P₀); determining, based on the matching point (MP), a plurality of matching edge points (MEPs) representing an edge radio frequency (RF) power value (P_{E}) that is greater than P₀ by a predetermined margin (P_{M}), wherein P_{E}=P₀+P_{M}; and determining at least one of a size and a center location of the impedance matching area (IMA) determined by the plurality of matching edge points (MEPs).

In an aspect, determining the plurality of matching edge points (MEPs) comprises, varying, at the matching point (MP), the first parameter (C1) until Pᵣ reaches P_{E} from P₀; setting a corresponding point as a first matching edge point (MEP₁) if Pᵣ reaches P_{E} at the corresponding point; and setting the remaining plurality of matching edge points (MEPs) by starting from the first matching edge point (MEP₁) and again reaching at or near the first matching edge point (MEP₁) in a zig-zag stepping manner, wherein the first parameter (C1) and the second parameter (C2) vary in a clockwise or counterclockwise direction relative to the matching point (MP).

In an aspect, setting the remaining plurality of matching edge points (MEPs) comprises, at any one of the plurality of matching edge points (MEPs), fixing one of the first parameter (C1) and the second parameter (C2) and varying the other until Pᵣ reaches a predetermined upper limit value (Pₘₐₓ) or a predetermined lower limit value (Pₘᵢₙ) from P_{E}, or reaches P_{E} again, wherein Pₘᵢₙ<P_{E}<Pₘₐₓ and Pₘᵢₙ≤Pᵣ≤Pₘₐₓ.

In an aspect, setting the remaining plurality of matching edge points (MEPs) further comprises, hanging one of the first parameter (C1) and the second parameter (C2) when Pᵣ reaches Pₘₐₓ or Pₘᵢₙ from P_{E}; and f Pᵣ reaches P_{E}, setting the corresponding point as a matching edge point (MEP) of the remaining plurality of matching edge points (MEPs).

In an aspect, setting the remaining plurality of matching edge points (MEPs) further comprises, changing one of the first parameter (C1) and the second parameter (C2) when Pᵣ reaches Pₘₐₓ or Pₘᵢₙ from P_{E}; if Pᵣ does not reach P_{E} and reaches Pₘₐₓ again, fixing one of the first parameter (C1) and the second parameter (C2) and varying the other; and if Pᵣ reaches P_{E}, setting the corresponding point as a matching edge point (MEP) of the remaining plurality of matching edge points (MEPs).

In an aspect, determining the plurality of matching edge points (MEPs) comprises, by varying the first parameter (C1) and the second parameter (C2) to follow a ridge width direction (a2) of the impedance matching area (IMA) at the matching point (MP), determining a first matching edge point (MEP₁) and a second matching edge point (MEP₂) that represent P_{E} and are opposite each other in the ridge width direction (a2); by varying the first parameter (C1) and the second parameter (C2) to follow a pole direction (a1) of the impedance matching area (IMA) from an intermediate point between the first matching edge point (MEP₁) and the second matching edge point (MEP₂), determining a third matching edge point (MEP₃) and a fourth matching edge point (MEP₄) that represent P_{E} and are opposite each other in the pole direction (a1); and by varying the first parameter (C1) and the second parameter (C2) to follow the ridge width direction (a2) from a midpoint between the third matching edge point (MEP₃) and the fourth matching edge point (MEP₄), obtaining a fifth matching edge point (MEP₅) and a sixth matching edge point (MEP₆) that represent P_{E} and are opposite each other in the ridge width direction (a2), and determining the size of a ridge width.

In an aspect, determining the plurality of matching edge points (MEPs) further comprises, by varying the first parameter (C1) and the second parameter (C2) parallel to the ridge width direction (a2) at a certain point on an axis connecting the MEP₃ and the MEP₄, determining additional matching edge points (MEPs) that represent P_{E} and are opposite each other in the ridge width direction (a2).

In an aspect, the impedance matching area (IMA) is determined by a midpoint between the MEP₃ and the MEP₄, a distance between the MEP₃ and the MEP₄, and the size of the ridge width.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 is a block diagram of an embodiment of a plasma control system in a substrate processing apparatus having an RF generator, a matching network, a plasma chamber and a control circuit (not shown).

FIG. 2 shows (a) Impedance space and (b) Gamma space for the plasma chamber impedance of Z1=10+i70.

FIG. 3 shows (a) Gamma space, (b) Z2 (Matcher-plasma chamber) Impedance, and (c) C1/C2 space for the constraint of Reflect %<1%.

FIG. 4 shows an enlarged view of the C1/C2 space of the region of interest in FIG. 3(c).

FIG. 5 shows another C1/C2 space representing reflected power ratios of 3% and 7%, respectively.

FIG. 6 shows another C1/C2 space representing reflected powers are less than 20 watt and 0.5 watt, respectively.

FIG. 7 shows an embodiment of the present invention to find the MEPs using a zig-zag stepping method.

FIG. 8 shows another embodiment of the present invention to find the MEPs using another zig-zag stepping method.

FIG. 9 shows alternative embodiment of the present invention to find the MEPs using pole and ridge width method.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

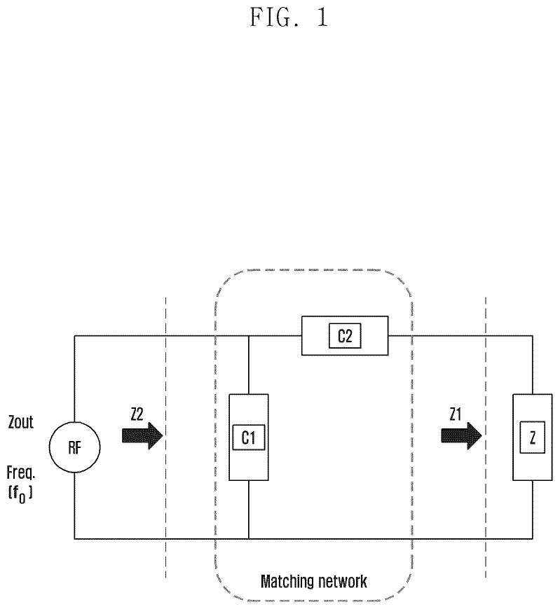

Referring to FIG. 1, a plasma control system in a substrate processing apparatus according to an embodiment of the present invention includes an RF generator, a matching network, a plasma chamber and a control circuit (not shown).

A semiconductor device can be a microprocessor, a memory chip, or other type of integrated circuit or device. A substrate can be placed in the plasma chamber, where the plasma chamber is configured to deposit a material layer onto the substrate or etch a material layer from the substrate. Plasma processing involves energizing a gas mixture by imparting energy to the gas molecules by introducing RF energy into the gas mixture. This gas mixture is typically contained in a vacuum chamber (the plasma chamber), and the RF energy is typically introduced into the plasma chamber through electrodes. Thus, the plasma can be energized by coupling RF power from an RF source into the plasma chamber to perform deposition or etching.

In a typical plasma process, the RF generator generates power at a radio frequency—which is typically within the range of 3 kHz and 300 GHz—and this power is transmitted through RF cables and networks to the plasma chamber. In order to provide efficient transfer of power from the RF generator to the plasma chamber, an intermediary circuit is used to match the fixed impedance of the RF generator with the variable impedance of the plasma chamber. Such an intermediary circuit is commonly referred to as an RF impedance matching network, or more simply as an RF matching network (hereinafter “RF matching network”). The purpose of the RF matching network is to transform the variable plasma impedance to a value that more closely matches the fixed impedance of the RF generator.

The exemplified matching network utilizes electronically variable capacitors (EVCs) for both a first variable impedance matching device (1^{st} VIMD) with a first parameter (C1) and a second variable impedance matching device (2^{nd} VIMD) with a second parameter (C2). It is noted that the invention is not so limited. For example, one of the EVCs may be a mechanically variable VVC, or may be replaced with a variable inductor.

As discussed above, the RF matching network serves to help maximize the amount of RF power transferred from the RF source to the plasma chamber by matching the impedance to the fixed impedance of the RF source. The RF matching network can consist of a single module within a single housing designed for electrical connection to the RF source and the plasma chamber. In other embodiments, the components of the RF matching network can be located in different housings, some components can be outside of the housing, and/or some components can share a housing with a component outside the RF matching network. As an example of the RF matching network, see, e.g., FIG. 1 of U.S. Pat. No. 10,707,057 B2, incorporated herein by reference in its entirety.

As is known in the art, the plasma within a plasma chamber typically undergoes certain fluctuations outside of operational control so that the impedance presented by the plasma chamber is a variable impedance. Since the variable impedance of the plasma chamber cannot be fully controlled, and an impedance matching network may be used to create an impedance match between the plasma chamber and the RF source. Moreover, the impedance of the RF source may be fixed at a set value by the design of the particular RF source. Although the fixed impedance of an RF source may undergo minor fluctuations during use, due to, for example, temperature or other environmental variations, the impedance of the RF source is still considered a fixed impedance for purposes of impedance matching because the fluctuations do not significantly vary the fixed impedance from the originally set impedance value. Other types of RF source may be designed so that the impedance of the RF source may be set at the time of, or during, use. The impedance of such types of RF sources is still considered fixed because it may be controlled by a user (or at least controlled by a programmable controller) and the set value of the impedance may be known at any time during operation, thus making the set value effectively a fixed impedance.

The RF source may be an RF generator of a type that is well-known in the art, and generates an RF signal at an appropriate frequency and power for the process performed within the plasma chamber. The RF source may be electrically connected to the RF impedance matching network using a coaxial cable, which for impedance matching purposes would have the same fixed impedance as the RF source.

The plasma in the plasma chamber enables one or both of deposition of materials onto the substrate and etching of materials from the substrate.

In the exemplified embodiment, the RF matching network includes a first variable impedance matching device (1^{st} VIMD) and a second variable impedance matching device (2^{nd} VIMD).

In the exemplified embodiment, each of the 1^{st} VIMD and 2^{nd} VIMD may be an electronic variable capacitor (EVC), as described in U.S. Pat. No. 7,251,121, the EVC being effectively formed as a capacitor array formed by a plurality of discrete capacitors.

In the exemplified embodiment, the control circuit includes a processor. The processor may be any type of properly programmed processing device (or collection of two or more processing devices working together), such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable matching network to perform the functions described herein.

The control circuit is the brains of the RF impedance matching network, as it receives multiple inputs, from sources such as the RF source and the EVCs, makes the calculations necessary to determine changes to the EVCs, and delivers commands to the EVCs to create the impedance match. The control circuit is of the type of control circuit that is commonly used in semiconductor fabrication processes, and therefore known to those of skill in the art. Any differences in the control circuit, as compared to control circuits of the prior art, arise in programming differences to account for the speeds at which the RF matching network is able to perform switching of the EVCs and impedance matching.

In FIG. 1, the EVC values (C1, C2) transform an impedance value Z1 of an actual plasma chamber to an impedance value Z2 of an effective plasma chamber as indicated below.

Z1(R+iX)→Z2(Z2_re+i Z2_im) for (C1,C2,f₀): impedance calculation

In this example of FIG. 1, the EVC values (C1, C2) and f₀ make a peculiar Z1 to Z2.

Gamma (voltage standing wave ratio) is defined as below.

Gamma=(Z2−Zout)/(Z2+Zout)

Using mathematical tools, the matching network is performing a 2-Dimensional mapping function between: control space, impedance space, and Gamma space.

Gamma value is related to reflect power ratio as set forth below.

Reflect %=[absolute(Gamma)]²

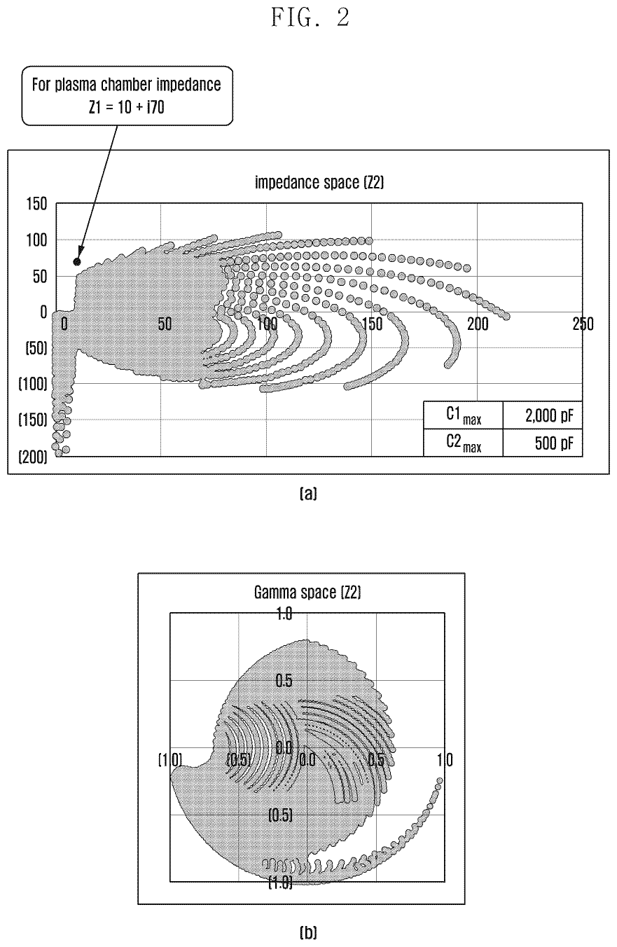

FIG. 2 shows (a) Impedance space and (b) Gamma space for the plasma chamber impedance of Z1=R+iX where R is 10 Ohm and X is 70 Ohm. In FIG. 2(a), C1 may vary up to 2,000 pF, while C2 may vary up to 500 pF. The Gamma space can be obtained by mapping the Impedance space as shown in FIG. 2(a) by using the formula of Gamma=(Z2−Zout)/(Z2+Zout) described above.

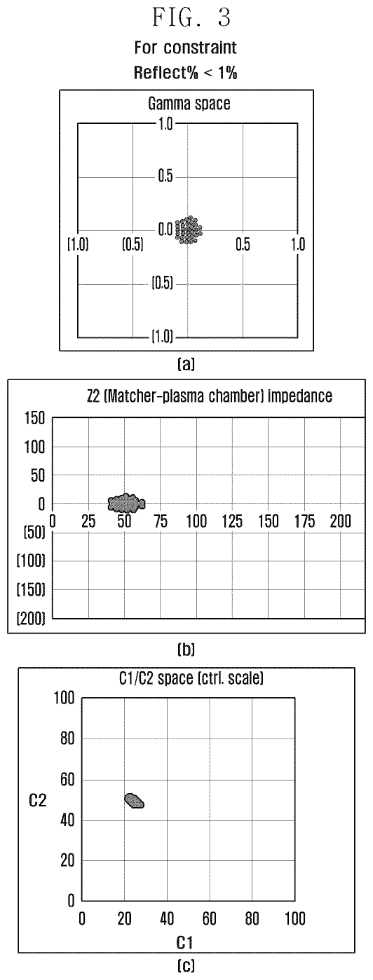

FIG. 3 shows (a) Gamma space, (b) Z2 (Matcher-plasma chamber) Impedance, and (c) C1/C2 space for the constraint of Reflect %<1%. In FIG. 3(c), the C1/C2 space is shown in controlled scale where C1=100×(C1_{actual}/C1ₘₐₓ), C2=100×(C2_{actual}/C2ₘₐₓ), and 0≤C1≤100 and 0≤C2≤100.

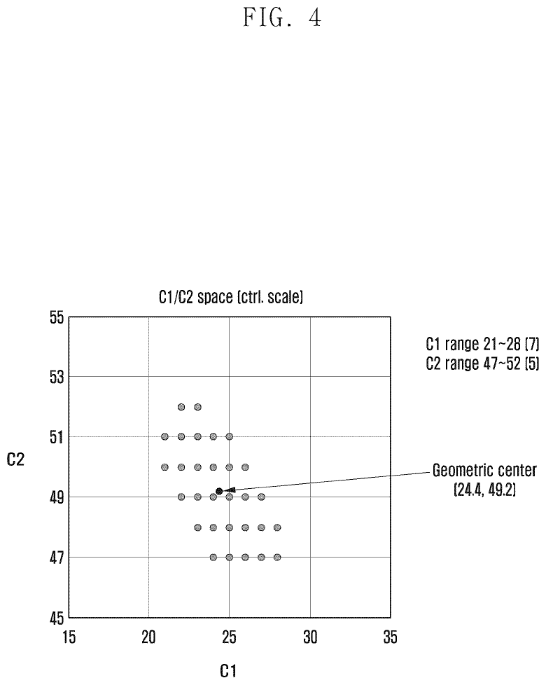

FIG. 4 shows an enlarged view of the C1/C2 space of the region of interest in FIG. 3(c), where the ranges of C1 and C2 of the region of interest are 21˜28 and 47˜52, respectively, and the geometric center is obtained as (24.4, 49.2).

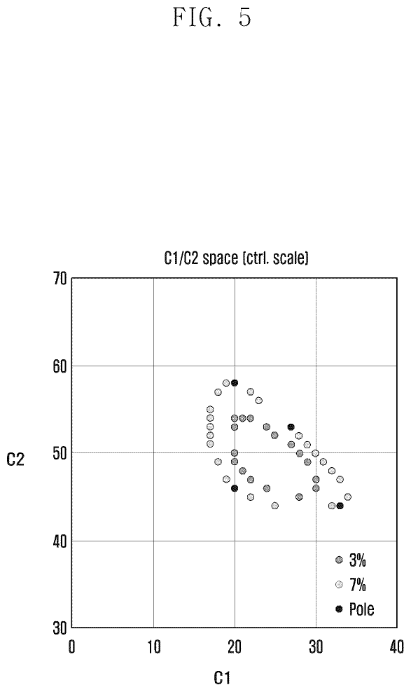

FIG. 5 shows another C1/C2 space representing reflected power ratios of 3% and 7%, respectively.

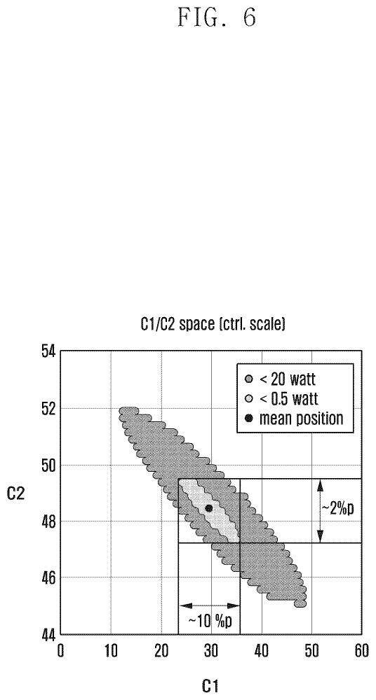

FIG. 6 shows an alternative C1/C2 space representing reflected powers are less than 20 watts and 0.5 watts, respectively, by using a scanning method. The scanning has been made under the plasma chamber conditions with 180 watts (driving power), N₂ (plasma gas) and a continuous wave (CW) input. The shape of the impedance matching area is substantially elliptical and the slope of the major axis can be found in FIG. 6: C2/C1=−0.2. Thus, if C1 moves d1, C2 also moves d1*(−0.2) for the major axis scan in FIG. 6.

There are two ways of specifying the RF impedance matching margin of the matching network, which are calculation and scanning.

First, one method of specifying the RF impedance matching margin of the matching network can be carried by calculating the matching data as follows: If the matching network characteristics are known and the relationship matrix is pre-stored for each plasma chamber impedance, the user can specify the matching margin from the measured chamber impedance, assuming that the plasma impedance is constant for small power variations. The calculated matching margin can be parameterized by matching the C1/C2 phase diagram area or two-dimensional topology features in this C1/C2 phase diagram area.

Second, the other method of specifying the RF impedance matching margin of the matching network can be carried by matcher scanning around a matching point as follows: The EVC values (C1, C2) can be varied under the constraint that the reflected power level is below a threshold. It will take time to scan, but it has the advantage of not having to measure the chamber impedance directly and not having to refer to the pre-stored data set. A separate RF power sensor can be used for scanning guidance.

Especially with the EVCs, the scan time would be a few hundred milliseconds, which is short enough for RF on time in the ALD process.

With the two methods described above, the advantageous effects of the present invention can be achieved in that the user can obtain the additional information such as the impedance matching area and an accurate optimal C1/C2 matching value set.

With the impedance matching area information, the user can quantitatively judge the stability of the RF system in the matching network and the plasma chamber with confidence. The impedance matching area is the C1/C2 position tolerance for the plasma chamber impedance (Z1).

Once the impedance matching area information is obtained, the geometric center in the area can be easily calculated to obtain the nominal matching point. This nominal matching point is a set of more accurate C1/C2 values for the plasma chamber impedance because it has the property of a mean value of the impedance matching area.

The process operation can also be performed on the matching edge points of the impedance matching area. If the matching edge point with greater reflected power is stable, the nominal matching point is more stable. The process at the edge pole can be compared to the process at the geometric center to judge the process stability. This intentional bias test can be used to test process stability and to adjust the threshold of the matching edge point.

According to one embodiment of the present invention, a method of determining an impedance matching area (IMA) in a plasma control system for a substrate processing apparatus is disclosed. Specifically, the method comprises: determining a first parameter (C1) of a first variable impedance matching device (1^{st} VIMD), a second parameter (C2) of a second variable impedance matching device (2^{nd} VIMD), and a reflected radio frequency (RF) power value (Pᵣ) reflected back to a radio frequency (RF) source, wherein Pᵣ varies depending on the values of the first parameter (C1) and the second parameter (C2); determining a matching point (MP) wherein Pᵣ is a specific value (P₀); determining, based on the matching point (MP), a plurality of matching edge points (MEPs) representing an edge radio frequency (RF) power value (P_{E}) that is greater than P₀ by a predetermined margin (P_{M}), wherein P_{E}=P₀+P_{M}; and determining at least one of a size and a center location of the impedance matching area (IMA) determined by the plurality of matching edge points (MEPs).

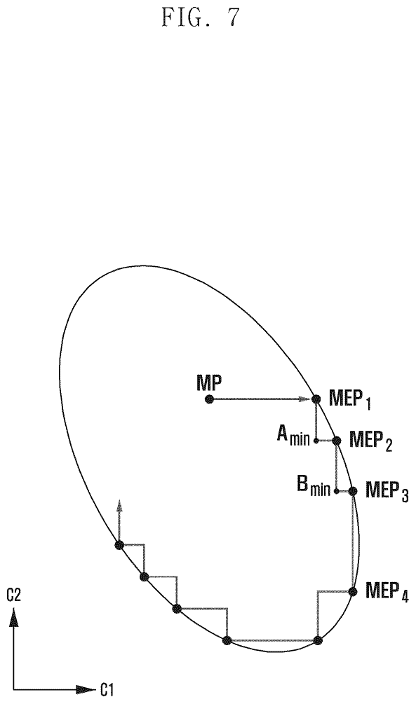

FIG. 7 shows an embodiment of the present invention to find the MEPs using a zig-zag stepping method.

At the matching point (MP), the first parameter (C1) is varied until Pᵣ reaches P_{E} from P₀.

Then, a corresponding point is set as a first MEP (MEP₁) if Pᵣ reaches P_{E} at the corresponding point. In other words, C1 moves from the MP to the MEP₁.

Then, the remaining plurality of MEPs is set by starting from the MEP₁ and again reaching at or near the MEP₁ in a zig-zag stepping manner, wherein the first parameter (C1) and the second parameter (C2) vary in a clockwise or counterclockwise direction relative to the matching point (MP).

In another embodiment of the present invention, at any one of the plurality of matching edge point (MEPs), one of the first parameter (C1) and the second parameter (C2) is fixed, and the other is varied until Pᵣ reaches a predetermined lower limit value (Pₘᵢₙ) from P_{E} (e.g., C2 moves from the MEP₁ to the Aₘᵢₙ or from the MEP₂ to the Bₘᵢₙ), or reaches P_{E} again (e.g., C2 moves from the MEP₃ to the MEP₄), wherein Pₘᵢₙ<P_{E} and Pₘᵢₙ≤Pᵣ≤P_{E}.

In other embodiment of the present invention, one of the first parameter (C1) and the second parameter (C2) is changed when Pᵣ reaches Pₘᵢₙ from P_{E}; and if Pᵣ reaches P_{E}, the corresponding point is set as a matching edge point (MEP) of the remaining plurality of matching edge points (MEPs). In other words, C1 moves from the Aₘᵢₙ to the MEP₂ or from the Bₘᵢₙ to the MEP₃.

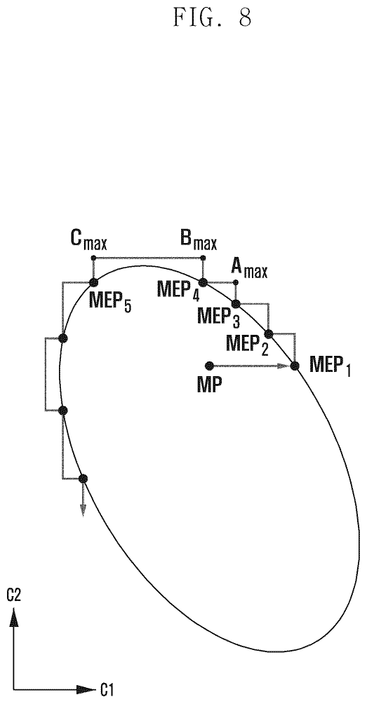

FIG. 8 shows another embodiment of the present invention to find the MEPs using another zig-zag stepping method.

At the matching point (MP), the first parameter (C1) is varied until Pᵣ reaches P_{E} from P₀.

Then, a corresponding point is set as a first MEP (MEP₁) if Pᵣ reaches P_{E} at the corresponding point. In other words, C1 moves from the MP to the MEP₁.

Then, the remaining plurality of MEPs is set by starting from the MEP₁ and again reaching at or near the MEP₁ in a zig-zag stepping manner, wherein the first parameter (C1) and the second parameter (C2) vary in a clockwise or counterclockwise direction relative to the matching point (MP).

In another embodiment of the present invention, at any one of the plurality of matching edge point (MEPs), one of the first parameter (C1) and the second parameter (C2) is fixed, and the other is varied until Pᵣ reaches a predetermined upper limit value (Pₘₐₓ) from P_{E} (e.g., C2 moves from the MEP₃ to the Aₘₐₓ or from the MEP₄ to the Bₘₐₓ), wherein P_{E}<Pₘₐₓ and P_{E}≤Pᵣ≤Pₘₐₓ.

In another embodiment of the present invention, one of the first parameter (C1) and the second parameter (C2) is changed when Pᵣ reaches Pₘₐₓ from P_{E}; and if Pᵣ reaches P_{E}, the corresponding point is set as a matching edge point (MEP) of the remaining plurality of matching edge points (MEPs). In other words, C1 moves from the Aₘₐₓ to the MEP₄.

In another embodiment of the present invention, one of the first parameter (C1) and the second parameter (C2) is changed when Pᵣ reaches Pₘₐₓ from P_{E}; if Pᵣ does not reach P_{E} and reaches Pₘₐₓ again (e.g., C1 moves from the Bₘₐₓ to the Cₘₐₓ), then one of the first parameter (C1) and the second parameter (C2) is fixed and the other is varied; and if Pᵣ reaches P_{E}, the corresponding point is set as a matching edge point (MEP) of the remaining plurality of matching edge points (MEPs). In other words, C1 moves from the Cₘₐₓ to the MEP₅.

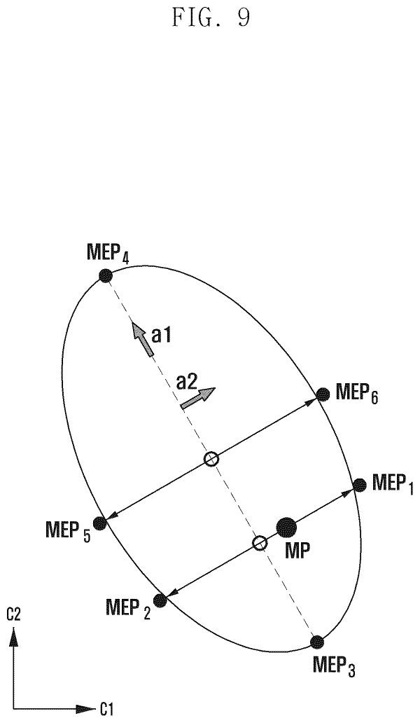

FIG. 9 shows another embodiment of the present invention to find the MEPs using pole and ridge width method.

By varying the first parameter (C1) and the second parameter (C2) to follow a ridge width direction (a2) of the impedance matching area (IMA) at the matching point (MP), it is possible to determine a first matching edge point (MEP₁) and a second matching edge point (MEP₂) that represent P_{E} and are opposite each other in the ridge width direction (a2). Then, by varying the first parameter (C1) and the second parameter (C2) to follow a pole direction (a1) of the impedance matching area (IMA) from an intermediate point between the first matching edge point (MEP₁) and the second matching edge point (MEP₂), it is possible to determine a third matching edge point (MEP₃) and a fourth matching edge point (MEP₄) that represent P_{E} and are opposite each other in the pole direction (a1). Then, by varying the first parameter (C1) and the second parameter (C2) to follow the ridge width direction (a2) from a midpoint between the third matching edge point (MEP₃) and the fourth matching edge point (MEP₄), it is possible to obtain a fifth matching edge point (MEP₅) and a sixth matching edge point (MEP₆) that represent P_{E} and are opposite each other in the ridge width direction (a2), and then to determine the size of a ridge width.

In another embodiment of the present invention, by varying the first parameter (C1) and the second parameter (C2) parallel to the ridge width direction (a2) at a certain point on an axis connecting the MEP₃ and the MEP₄, it is possible to determine additional matching edge points (MEPs) that represent P_{E} and are opposite each other in the ridge width direction (a2).

In another embodiment of the present invention, the impedance matching area (IMA) is determined by a midpoint between the MEP₃ and the MEP₄, a distance between the MEP₃ and the MEP₄, and the size of the ridge width.

While the embodiments discussed herein use one or more variable capacitors in a matching network to achieve an impedance match, it is noted that any variable reactance element can be used. A variable reactance element can include one or more discrete reactance elements, where a reactance element is a capacitor or inductor or similar reactive device.

While the inventions have been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

The above-described arrangements of apparatus and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A substrate processing apparatus, comprising:
a radio frequency (RF) source configured to generate an RF;
a plasma chamber configured to process substrates; and
a plasma control system, wherein the plasma control system comprising:
an impedance matching network (IMN), operably coupled between the RF source and the plasma chamber, comprising a first variable impedance matching device (1^{st} VIMD) and a second variable impedance matching device (2^{nd} VIMD); and
a control circuit operably coupled to the impedance matching network (IMN), the control circuit is configured to:
determine a first parameter (C1) of the first variable impedance matching device (1^{st} VIMD), a second parameter (C2) of the second variable impedance matching device (2^{nd} VIMD), and a reflected radio frequency (RF) power value (Pᵣ) reflected back to the radio frequency (RF) source, wherein Pᵣ varies depending on the values of the first parameter (C1) and the second parameter (C2);
determine a matching point (MP) where the Pᵣ is a specific value (P₀);
determine, based on the matching point (MP), a plurality of matching edge points (MEPs) representing an edge radio frequency (RF) power value (P_{E}) that is greater than P₀ by a predetermined margin (P_{M}), wherein P_{E}=P₀+P_{M}; and
determine at least one of a size and a center location of an impedance matching area (IMA) determined by the plurality of matching edge points (MEPs).

2. A method of determining an impedance matching area (IMA) in a plasma control system for a substrate processing apparatus, the method comprising:
determining a first parameter (C1) of a first variable impedance matching device (1^{st} VIMD), a second parameter (C2) of a second variable impedance matching device (2^{nd} VIMD), and a reflected radio frequency (RF) power value (Pᵣ) reflected back to a radio frequency (RF) source, wherein Pᵣ varies depending on the values of the first parameter (C1) and the second parameter (C2);
determining a matching point (MP) wherein Pᵣ is a specific value (P₀);
determining, based on the matching point (MP), a plurality of matching edge points (MEPs) representing an edge radio frequency (RF) power value (P_{E}) that is greater than P₀ by a predetermined margin (P_{M}), wherein P_{E}=P₀+P_{M}; and
determining at least one of a size and a center location of the impedance matching area (IMA) determined by the plurality of matching edge points (MEPs).

3. The method of claim 2, wherein determining the plurality of matching edge points (MEPs) comprises,
varying, at the matching point (MP), the first parameter (C1) until Pᵣ reaches P_{E} from P₀;
setting a corresponding point as a first matching edge point (MEP₁) if Pᵣ reaches P_{E} at the corresponding point; and
setting the remaining plurality of matching edge points (MEPs) by starting from the first matching edge point (MEP₁) and again reaching at or near the first matching edge point (MEP₁) in a zig-zag stepping manner,
wherein the first parameter (C1) and the second parameter (C2) vary in a clockwise or counterclockwise direction relative to the matching point (MP).

4. The method of claim 3, wherein setting the remaining plurality of matching edge points (MEPs) comprises,
at any one of the plurality of matching edge points (MEPs), fixing one of the first parameter (C1) and the second parameter (C2) and varying the other until Pᵣ reaches a predetermined upper limit value (Pₘₐₓ) or a predetermined lower limit value (Pₘᵢₙ) from P_{E}, or reaches P_{E} again, wherein Pₘᵢₙ<P_{E}<Pₘₐₓ and Pₘᵢₙ≤Pᵣ≤Pₘₐₓ.

5. The method of claim 4, wherein setting the remaining plurality of matching edge points (MEPs) further comprises,
changing one of the first parameter (C1) and the second parameter (C2) when Pᵣ reaches Pₘₐₓ or Pₘᵢₙ from P_{E}; and
if Pᵣ reaches P_{E}, setting the corresponding point as a matching edge point (MEP) of the remaining plurality of matching edge points (MEPs).

6. The method of claim 4, wherein setting the remaining plurality of matching edge points (MEPs) further comprises,
changing one of the first parameter (C1) and the second parameter (C2) when Pᵣ reaches Pₘₐₓ or Pₘᵢₙ from P_{E};
if Pᵣ does not reach P_{E} and reaches Pₘₐₓ again, fixing one of the first parameter (C1) and the second parameter (C2) and varying the other; and
if Pᵣ reaches P_{E}, setting the corresponding point as a matching edge point (MEP) of the remaining plurality of matching edge points (MEPs).

7. The method of claim 2, wherein determining the plurality of matching edge points (MEPs) comprises,
by varying the first parameter (C1) and the second parameter (C2) to follow a ridge width direction (a2) of the impedance matching area (IMA) at the matching point (MP), determining a first matching edge point (MEP₁) and a second matching edge point (MEP₂) that represent P_{E} and are opposite each other in the ridge width direction (a2);
by varying the first parameter (C1) and the second parameter (C2) to follow a pole direction (a1) of the impedance matching area (IMA) from an intermediate point between the first matching edge point (MEP₁) and the second matching edge point (MEP₂), determining a third matching edge point (MEP₃) and a fourth matching edge point (MEP₄) that represent P_{E} and are opposite each other in the pole direction (a1); and
by varying the first parameter (C1) and the second parameter (C2) to follow the ridge width direction (a2) from a midpoint between the third matching edge point (MEP₃) and the fourth matching edge point (MEP₄), obtaining a fifth matching edge point (MEP₅) and a sixth matching edge point (MEP₆) that represent P_{E} and are opposite each other in the ridge width direction (a2), and determining the size of a ridge width.

8. The method of claim 7, wherein determining the plurality of matching edge points (MEPs) further comprises,
by varying the first parameter (C1) and the second parameter (C2) parallel to the ridge width direction (a2) at a certain point on an axis connecting the MEP₃ and the MEP₄, determining additional matching edge points (MEPs) that represent Pᵣ and are opposite each other in the ridge width direction (a2).

9. The method of claim 7, wherein the impedance matching area (IMA) is determined by a midpoint between the MEP₃ and the MEP₄, a distance between the MEP₃ and the MEP₄, and the size of the ridge width.
